(19) United States
(12) Patent Application Publication
(10) Pub. No.: US 2024/0290742 A1
(43) Pub. Date: Aug. 29, 2024

(54) PATTERNED ADHESIVE IN CAVITIES FOR MICRO-TRANSFER PRINTING

(71) Applicant: X-Celeprint Limited, Dublin (IE)

(72) Inventors: Ruggero Loi, Selargius (IT); Ronald S. Cok, Rochester, NY (US)

(21) Appl. No.: 18/584,370

(22) Filed: Feb. 22, 2024

Related U.S. Application Data
(60) Provisional application No. 63/448,653, filed on Feb. 27, 2023.

(51) Int. Cl. H01L 23/00

(52) U.S. Cl. CPC H01L 24/32; H01L 24/83; H01L 2224/32145; H01L 2224/32225; H01L 2224/83

(57) ABSTRACT

A printed structure includes a target substrate having a target-substrate surface, a structure disposed in or on the target substrate, the structures having a structure side that extends at least partially orthogonal to the target-substrate surface, a patterned adhesive layer disposed on the target-substrate surface not in contact with the structure side, and a component having a component side, the component disposed on the patterned adhesive layer with the component side adjacent to the structure side.

### CROSS REFERENCE TO RELATED APPLICATION

Reference is made to U.S. patent application Ser. No. 17/955,346 filed Sep. 28, 2022, entitled High-Precision Structures and Methods of Making by Loi et al., the disclosure of which is incorporated by reference herein in its entirety.

### TECHNICAL FIELD

The present disclosure relates to micro-transfer printing components from a source wafer to a destination substrate with improved alignment accuracy using a transfer element, such as a stamp.

### BACKGROUND

Substrates with electronically active components distributed over the extent of the substrate may be used in a variety of electronic systems, for example, in flat-panel display devices such as flat-panel liquid crystal or organic light emitting diode (OLED) displays, in imaging sensors, and in flat-panel solar cells. The electronically active components are typically either assembled on the substrate, for example using individually packaged surface-mount integrated-circuit devices and pick-and-place tools, or by depositing (e.g., sputtering or spin coating) a layer of semiconductor material on the substrate and then photolithographically processing the semiconductor material to form thin-film circuits on the substrate. Individually packaged integrated-circuit devices typically have smaller transistors with higher performance than thin-film circuits but the packages are larger than can be desired for highly integrated systems.

Other methods for transferring active components from one substrate to another are described in U.S. Pat. No. 7,943,491. In an example of these approaches, small integrated circuits are formed on a native semiconductor source wafer. The small unpackaged integrated circuits, or chiplets, are released from the native source wafer by etching a layer formed beneath the circuits. A viscoelastic stamp is pressed against the native source wafer and the process side of the chiplets is adhered to individual stamp posts. The chiplets on the stamp are then pressed against a destination substrate or backplane with the stamp and adhered to the destination substrate. In another example, U.S. Pat. No. 8,722,458 entitled Optical Systems Fabricated by Printing-Based Assembly teaches transferring light-emitting, light-sensing, or light-collecting semiconductor elements from a wafer substrate to a destination substrate or backplane. In certain applications, it can be important for transferred components to be located precisely and accurately on a destination substrate or backplane. When components are accurately located, they can be positioned closer together to form denser and smaller systems with improved performance. In particular, printed devices can be more accurately positioned with each other or with respect to photolithographically defined wires. For example, accurately positioned opto-electronic devices experience fewer conversion or connection losses. There is a need, therefore, for methods, devices, and structures to enable precise and accurate printing of components.

### SUMMARY

The present disclosure provides, inter alia, structures, materials, and methods that enable precise and accurate printing (e.g., micro-transfer printing) of components from a native source wafer to a non-native target substrate in alignment with structures disposed on the target substrate. In some embodiments, components are micro-transfer printed into a cavity with improved alignment or in closer proximity to cavity structures or sidewalls.

In some aspects, the present disclosure is directed to a printed structure. The printed structure can include a target substrate having a target-substrate surface. The printed structure can further include a structure disposed in or on the target substrate, the structure having a structure side (e.g., that extends at least partially orthogonal to the target-substrate surface). The printed structure can further include a patterned adhesive layer disposed on the target-substrate surface not in contact with the structure side. The printed structure can further include a component having a component side, the component disposed on the patterned adhesive layer with the component side adjacent to the structure side.

In some embodiments, the component side is within one micron (e.g., within 1.0 micron, within 0.75 micron, within 0.5 micron, within 0.25 micron, or within 0.1 micron) of the structure side.

In some embodiments, the component is non-native to the target substrate and non-native to the structure [e.g., wherein the component comprises a component substrate that is non-native to (e.g., separate, independent, and distinct) from the target substrate and from the structure].

In some embodiments, the component comprises a broken (e.g., fractured) or separated component tether. In some embodiments, the component tether is disposed on a second side of the component different from the component side.

In some embodiments, the structure side is substantially planar.

In some embodiments, the structure comprises two adjacent structure sides, the component comprises two adjacent component sides, the patterned adhesive layer is disposed on the target-substrate surface not in contact with either of the two adjacent structure sides, and the component is disposed on the adhesive layer with each of the two adjacent component sides adjacent to a corresponding one of the two adjacent structure sides.

In some embodiments, the adhesive layer has a thickness over the target substrate that is no greater than one micron (e.g., no greater than five hundred nm, two hundred fifty nm, one hundred nm, sixty nm, fifty nm, thirty nm, twenty nm, ten nm, or five nm).

In some embodiments, the printed structure comprises a cavity extending into the target substrate, wherein the cavity comprises a cavity bottom and cavity walls, the cavity bottom is at least a portion of the target-substrate surface, and the structure comprises a portion of the target substrate forming the cavity, and the cavity wall forms the structure side.

In some embodiments, the adhesive layer comprises a soft-cured adhesive. In some embodiments, the adhesive layer comprises a hard-cured adhesive.

In some embodiments, the component side is in physical contact with the structure side. In some embodiments, the component side is substantially parallel to the structure side.

In some embodiments, the printed structure comprises multiple components each non-native to the target substrate and each having a component side disposed adjacent to the structure side.

In some embodiments, the printed structure comprises two or more structures (e.g., wherein each structure of the two or more structures has a structure side and the structure sides of the two or more of the structures are in a substantially common plane). In some embodiments, the component side is substantially parallel to the structure sides. In some embodiments, the structure sides are not parallel. In some embodiments, the structure sides form an angle less than 180 degrees (e.g., no greater than 150 degrees, no greater than 90 degrees, or less than 90 degrees). In some embodiments, the component is disposed within the angle formed by the structure sides.

In some embodiments, (i) the component side is substantially orthogonal to the target-substrate surface, (ii) the structure side is substantially orthogonal to the target-substrate surface, or (iii) both (i) and (ii).

In some aspects, the present disclosure is directed to a method of making a printed structure. In some embodiments, the method comprises providing a target substrate and one or more structures extending from a target-substrate surface of the target substrate (e.g., wherein the structures are spatially separated independent structures) and wherein each of the one or more structures has a structure side (e.g., that extends at least partially orthogonal to the target-substrate surface). In some embodiments, the method comprises providing a patterned adhesive layer on the target-substrate surface of the target substrate so that the adhesive layer is not in contact with the structure side. In some embodiments, the method comprises providing a transfer element and a component adhered to the transfer element (e.g., wherein the component comprises a component substrate that is separate and independent from the target substrate). In some embodiments, the method comprises disposing the component on the adhesive layer with the transfer element. In some embodiments, the method comprises separating the transfer element from the component, thereby printing the component to the target substrate.
moving the transfer element with the adhered component horizontally towards at least one of the structures at least until the component side physically contacts a structure side of at least one of the structures before the component is disposed on the adhesive layer with the transfer element.

In some embodiments, the method comprises moving the transfer element with the adhered component horizontally towards at least one of the structures at least until the component side physically contacts a structure side at least one of the structures after the component is disposed on the adhesive layer with the transfer element.

In some embodiments, the method comprises moving the transfer element with the adhered component horizontally towards at least one of the structures at least until the component side physically contacts a structure side at least one of the structures at the same time that the component is moved vertically and disposed on the adhesive layer with the transfer element.

In some embodiments, the one or more structures comprise two or more structures having sides forming an angle less than 180 degrees and wherein the transfer element moves the component horizontally towards two structure sides (i) at the same time or (ii) sequentially.

Some embodiments of the present disclosure provide methods, devices, and structures that enable precise and accurate micro-transfer printing components from a native source wafer to a non-native destination substrate. The components can be aligned with structures and can be optical components.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1A is a perspective of a printed structure according to illustrative embodiments of the present disclosure;

FIG. 1B is a cross section of a printed structure corresponding to FIG. 1A according to illustrative embodiments of the present disclosure;

FIG. 2 is a flow diagram of methods according to illustrative embodiments of the present disclosure;

FIGS. 3A-3G are successive cross sections of structures according to illustrative methods and embodiments of the present disclosure;

FIG. 4A is a perspective of a printed structure with a cavity according to illustrative embodiments of the present disclosure;

FIG. 4B is a cross section of a printed structure with a cavity corresponding to FIG. 4A according to illustrative embodiments of the present disclosure; and

FIGS. 5-9 are perspectives of printed structures according to illustrative embodiments of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not necessarily drawn to scale.

### DETAILED DESCRIPTION OF CERTAIN EMBODIMENTS

Certain embodiments of the present disclosure are directed toward methods of printing (e.g., micro-transfer printing) components from a component source wafer onto a target substrate using a transfer element (e.g., stamp or other transfer device), and aligning the components to structures extending from or into a surface of the target substrate. The structures can be used to align components to a location on the target substrate, to the structure, or to another component. Transfer-printed components can be moved both vertically and horizontally over the target substrate to contact the structure and position the component on the target substrate with respect to the structure. The structure and the component can be aligned optical components.

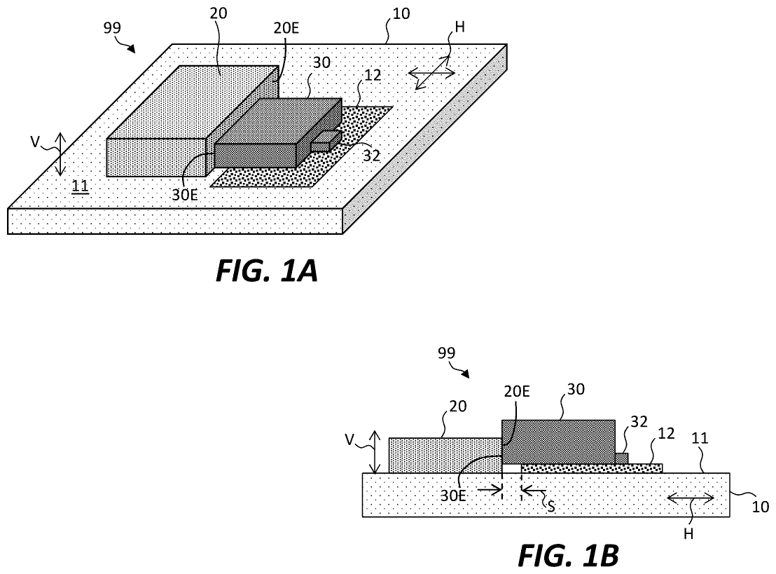

According to embodiments of the present disclosure and as illustrated in FIGS. 1A and 1B, a printed structure 99 comprises a target substrate 10 having a target-substrate surface 11 and a structure 20 or structures 20 disposed in or on target substrate 10. Structures 20 have a structure side 20E that extends at least partially orthogonal to target-substrate surface 11 in a vertical direction V. Structure 20 can extend away from target substrate 10 or into target substrate 10. A patterned adhesive layer 12 (or adhesive 12) can be disposed on target-substrate surface 11 not in contact with structure side 20E. For example, patterned adhesive layer 12 can be disposed on target-substrate surface 11 a separation distance S away or separated from structure side 20E in a horizontal direction H parallel to target-substrate surface 11. A component 30 having a component side 30E can be disposed on patterned adhesive layer 12 with component side 30E adjacent to structure side 20E. Component side 30E can extend at least partially orthogonal to target-substrate surface 11 in vertical direction V. Adjacent component side 30E can be closer to structure side 20E than any other portion of component 30.

Component side 30E can be disposed on patterned adhesive layer 12 within one micron (e.g., within 1.0 micron, within 0.75 micron, within 0.5 micron, within 0.25 micron, or within 0.1 micron) of structure side 20E. In some embodiments, component side 30E is in physical contact with structure side 20E. In some embodiments, component side 30E is parallel to structure side 20E. In some embodiments and as shown in FIG. 1A, adhesive layer 12 can extend beyond component 20 on sides other than component side 30E adjacent to structure side 20E. In some embodiments, adhesive layer 12 does not extend beyond component 20 on one or more sides of component 30 other than component side 30E adjacent to structure side 20E. In some embodiments, adhesive layer 12 is disposed only between component 20 and target substrate 10 so that all of adhesive layer 12 is disposed only between component 20 and target substrate 10 (not shown in the Figures). In some embodiments, adhesive layer 12 is disposed beneath at least 50%, 60%, 70%, 80%, or 90% of a bottom surface of component 30 and between component 30 and target substrate 11. A greater area of bottom surface of component 30 in contact with adhesive layer 12 can improve component 30 adhesion to target substrate 10.

Component 30 can comprise a component substrate that is separate, independent, and distinct from target substrate 10 and from structure 20 so that component 30 is non-native to target substrate 10 and non-native to structure 20 on or in target substrate 10. Component 30 can be disposed on patterned adhesive layer 12 adjacent to structure 20 by micro-transfer printing component 30 from a component source substrate and can comprise a fractured or separated component tether 32 in consequence. Component tether 32 can be disposed on a second, e.g., different, side than component side 30E adjacent to structure side 20E, for example on an opposite or adjacent side of component 30 from component side 30E in a horizontal direction parallel to target-substrate surface 11. Component 30 can be an electrical, optical, or electro-optic component, for example an active or passive electrical, optical, or electro-optic component 30. All

In embodiments of the present disclosure, target substrate 10 can comprise a semiconductor (such as silicon), a compound semiconductor, glass, ceramic, or plastic. Suitable target substrates 10 are found in the integrated circuit or display industries. Target substrate 10 can comprise a substrate circuit (e.g., an electronic circuit) used to control or respond to component 30, for example component 30 can be electrically connected to a substrate circuit formed in or on target substrate 10, for example a CMOS circuit.

Structure 20 can be formed on or in and native to target substrate 10 but is not necessarily so. Structure 20 can comprise a patterned inorganic material, such as an oxide or nitride (e.g., silicon oxide or silicon nitride) and can be structured to comprise optical or electrical elements, for example wave guides.

In some embodiments, structure side 20E can be substantially planar and can be substantially orthogonal to target-substrate surface 11 but is not necessarily so. Likewise, in some embodiments, component side 30E can be substantially planar and can be substantially orthogonal to target-substrate surface 11 but is not necessarily so. Component side 30E can be substantially parallel to structure side 20E but is not necessarily so.

Target substrate 10, structure 20, and component 30 can be constructed using photolithographic methods and materials known in the art. Component 30 and structure can be micron-scale, for example having an extent no greater than one thousand microns in length or width (e.g., no greater than five hundred, two hundred fifty, one hundred, fifty, twenty, ten, or five microns) and a thickness (or height) over target substrate 10 no greater than two hundred microns (e.g., no greater than one hundred microns, fifty microns, twenty microns, ten microns, five microns, four microns, three microns, two microns, or one micron). Adhesive layer 12 can have a thickness over target substrate 10 no greater than one micron, five hundred nm, two hundred fifty nm, one hundred nm, sixty nm, fifty nm, thirty nm, twenty nm, ten nm, or five nm. Adhesive layer 12 can be a curable adhesive deposited in a liquid state and then cured.

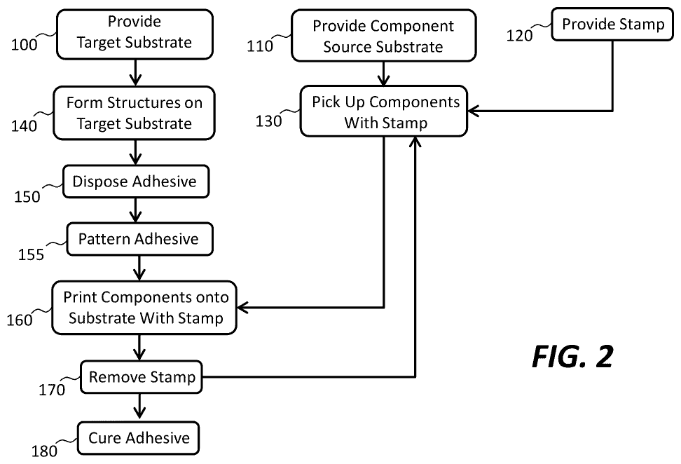

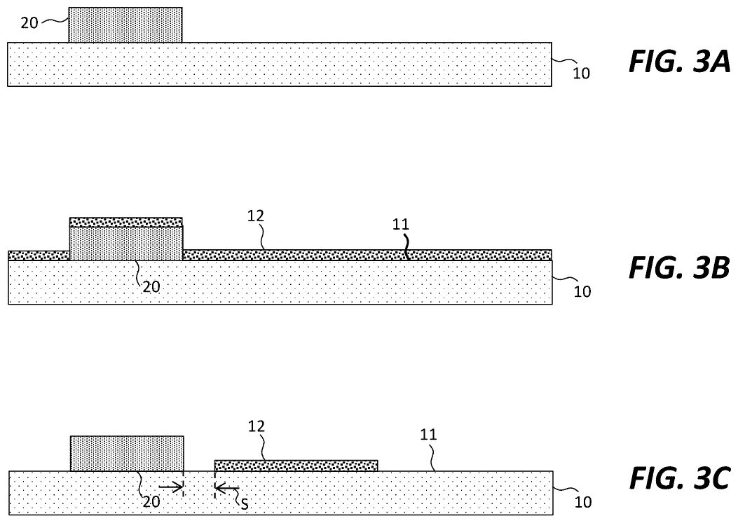

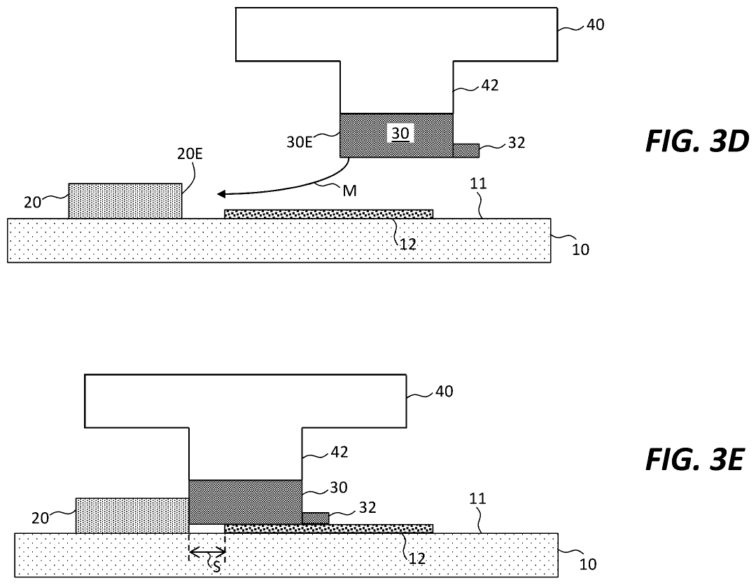

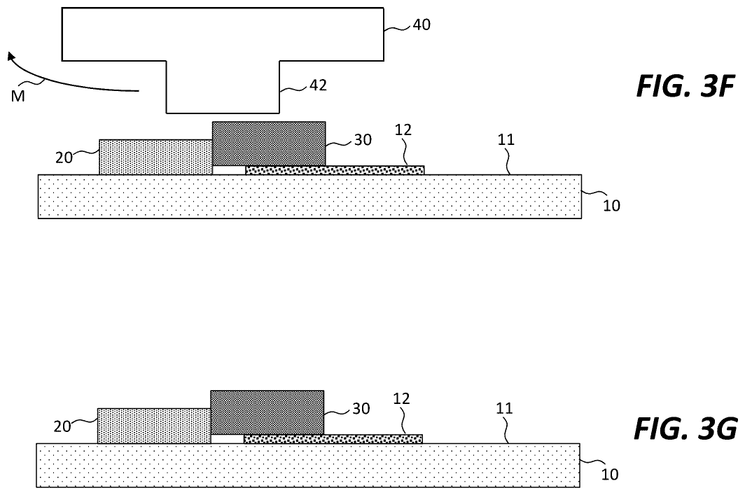

Embodiments of the present disclosure can be constructed as illustrated in the flow diagram of FIG. 2 and the successive structures illustrated in FIGS. 3A-3G. As shown in FIG. 3A, a target substrate 10 (for example a target for a micro-transfer printed component 30) is provided in step 100 and a structure 20 having a structure side 20E is formed in step 140 on or in target substrate 10, as illustrated in FIG. 3B, for example using photolithographic methods and materials.

An adhesive layer 12 is disposed over target substrate 10 and structure 20 in step 150 and patterned in step 155 as shown in FIG. 3C so that adhesive 12 is not in contact with structure side 20E, for example adhesive layer 12 and structure side 20E are separated by a separation distance S. Separation distance S can be but is not limited to a distance no greater than five nm, ten nm, twenty nm, fifty nm, one hundred nm, two hundred nm, five hundred nm, one micron, micron, two microns, five microns, or ten microns. Adhesive layer 12 can comprise, for example Intervia or BCB (benzocyclobutene) coated by spin or spray coating in a liquid state to a thickness no greater than one hundred, sixty, fifty, forty, thirty, twenty, ten, or five nm. Patterning step 155 can soft-cure adhesive layer 12 but, according to some embodiments is not hard-cured or finally cured during patterning step 155. Patterning step 155 can be accomplished by using conventional photolithographic photoresist methods including masked exposure and etching. By patterning adhesive layer 12 so that it is separated from and not in contact with structure side 20E, liquid adhesive 12 does not wick up onto structure side 20E.

A component source substrate (e.g., a semiconductor wafer) with components 30 can be provided in step 110, and a stamp 40, for example with a stamp post 42, provided in step 120. Components 30 can be released from the component source substrate by under-etching components 30 so that components 30 are suspended over a gap by a component tether 32 physically connected to an anchor portion of the component source substrate. Stamp 40 can be controlled by a motion-plus-optics platform to contact stamp post 42 to a component 30 on the component source substrate to pick up and adhere component 30 to stamp 40 in step 130. Picking component 30 can fracture or separate component tether 32. Stamp 40 and component 30 are transported by the motion-plus-optics platform to target substrate 10 and component 30 is printed using micro-transfer printing onto patterned adhesive layer 12 with stamp 40 in step 160 for example in direction M as shown in FIG. 3D with component side 30E adjacent to structure side 20E, for example in physical contact with or within one micron of structure side 20E, as shown in FIG. 3E. Stamp 40 can then be removed in step 170 and as shown in FIG. 3F by moving stamp 40 in direction M with the motion-plus-optics platform or tool. Patterned adhesive layer 12 can then be hard-cured in step 180, for example with heat or exposure to ultra-violet radiation, forming printed structure 99 as shown in FIG. 3G.

By patterning adhesive layer 12 so that it is not in contact with structure side 20E, liquid adhesive 12 is not pushed into contact with structure side 20E by the micro-transfer printing process. By preventing any deposition or movement of adhesive 12 onto structure side 20E, component side 30E can approach more closely to structure side 20E, for example can physically contact structure side 20E, because there is no adhesive 12 between component side 30E and structure side 20E. Such close alignment or contact between structure side 20E and component side 30E can facilitate the efficient transmission of light from one to the other, for example light insertion losses are reduced or eliminated, improving the function of printed structures 99 that are photonic systems. For example, structure 20 or component 30 can be any one of aligned optical components, such as waveguides, lasers, light emitters, light sensors, light amplifiers, light modulators in a photonic system.

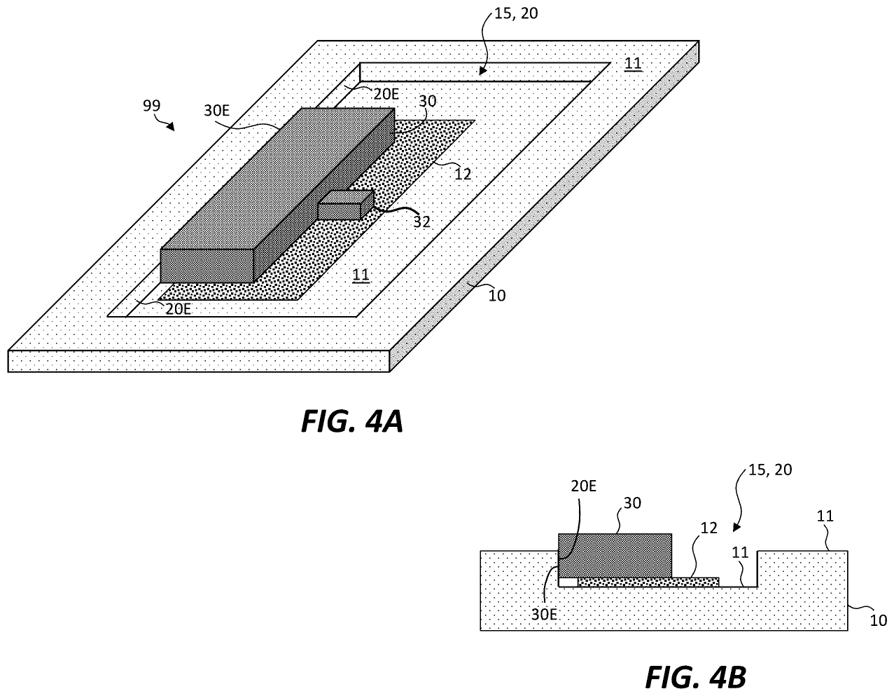

In some embodiments of the present disclosure and as illustrated in FIGS. 4A and 4B, a printed structure 99 comprises a target substrate 10 with a cavity 15 disposed in and extending into target substrate 10. Cavity 15 can comprise a cavity bottom and cavity walls. According to embodiments of the present disclosure, a portion of target substrate comprising cavity 15 can be structure 20. The cavity bottom can be a portion of target-substrate surface 11 and a cavity wall can be at least a portion of structure side 20E. Component 30 can be micro-transfer printed into cavity 15 with component side 30E adjacent to a cavity wall serving as structure side 20E. This configuration can be useful when, for example, a waveguide is formed in target substrate 10 and extends to a cavity wall and component 30 receives or transmits light into the waveguide.

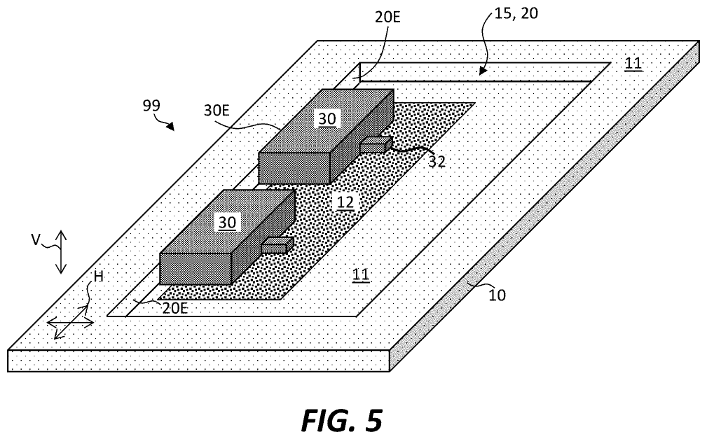

According to some embodiments of the present disclosure and as shown in FIG. 5, printed structures 99 comprise multiple components 30. Each component 30 can be non-native to target substrate 10 and each can have a component side 30E disposed adjacent to structure side 20E, for example in contact with or with one micron of structure side 20E. The multiple component sides 30E can be in a common plane.

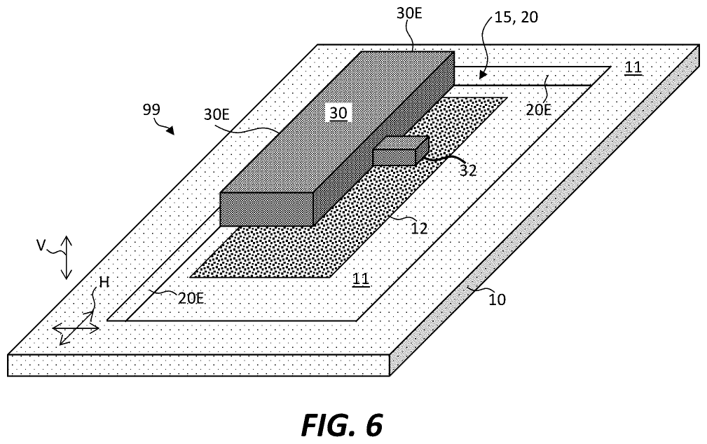

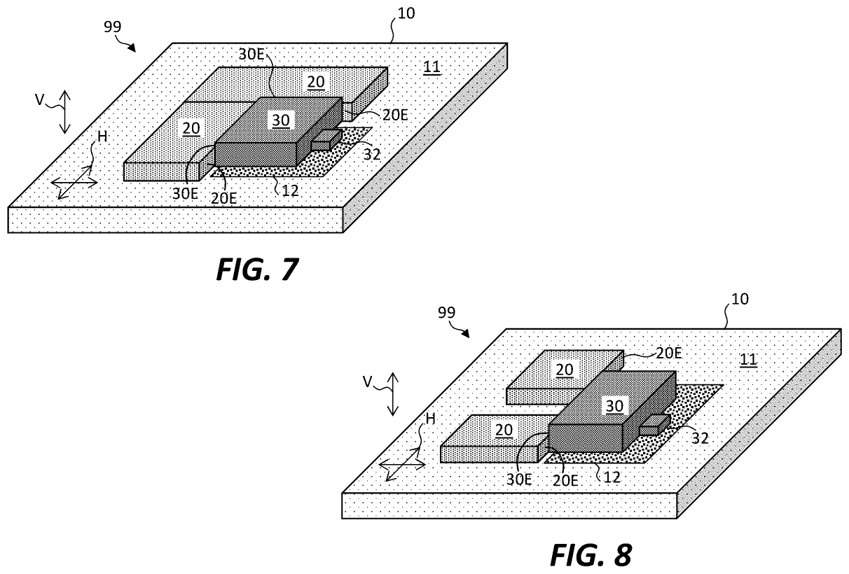

Some embodiments of the present disclosure and as shown in FIG. 6 (with a structure 20 comprising cavity 15) and FIG. 7 (with structure 20 extending vertically away from target substrate 10) comprise a structure 20 with a structure side 20E having multiple planes, for example forming multiple (e.g., two) walls at an angle of less than 180 degrees, for example not greater than 150, 90, 60, 45, or 30 degrees. Alternatively, the multiple planes could each be considered a separate structure side 20E. Corresponding multiple component sides 30E of component 30 can be disposed against the multiple walls forming one or more structure sides 20E. In such configurations, the location of component 30 with respect to structure 20 can be controlled in two dimensions, by pressing component 30 horizontally against both walls with stamp 40 in step 160, enabling more precise alignment between component 30 and structure 20.

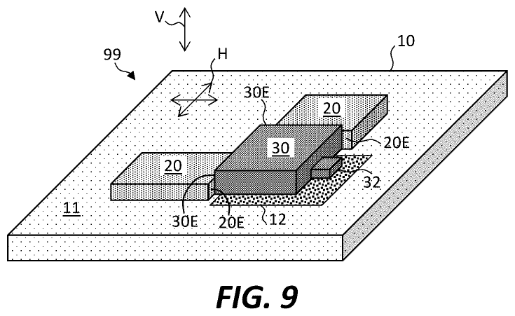

Some embodiments and as shown in FIG. 8 comprise two or more structures 20. Each structure 20 of the two or more structures 20 has a structure side 20E and structure sides 20E of the two or more of structures 20 can be in a substantially common plane (as shown in FIG. 8) or can be disposed at an angle less than 180 degrees, for example 150 degrees, or 90 degrees (as shown in FIG. 9) so that structure sides 20E are in different planes. Component 30 can be disposed within the angle (e.g., 90 degree angle) formed by structure sides 20E, thereby enabling two-dimensional alignment of component 30 during micro-transfer printing. For example, stamp 40 can move component 30 horizontally (e.g., parallel to target-substrate surface 11) towards both structure sides 20E of structures so that contact between component sides 30E of component 30 with structure sides 20E of structures 20 will move component 30 into alignment with structures 20.

Thus, methods according to embodiments of the present disclosure can comprise moving transfer element 40 (e.g., stamp 40) with adhered component 30 horizontally towards at least one of structures 20 at least until component side 30E physically contacts a structure side 20E of at least one of structures 20 before or after component 30 is disposed on adhesive layer 12 with transfer element 40. In some embodiments, transfer element 40 with adhered component 30 can move both vertically towards adhesive layer 12 and horizontally toward one or more structure sides 20E at a same time, for example in direction M as shown in FIG. 3D. Transfer element 40 can move component 30 horizontally towards two structure sides 20E at the same time or sequentially.

Other structures and methods are found in U.S. patent application Ser. No. 17/955,346 entitled High-Precision Structures and Methods of Making. Such other structures and methods can be combined with the patterned adhesive layer 12 of the present disclosure.

In embodiments of the present disclosure, target substrate 10 is provided without structure 20 and structure 20 is constructed on or adhered to target substrate 10 in step 140. Structure 20 can be formed or constructed on target substrate 10. Structure 20 can be disposed, e.g., by micro-transfer printing, on target-substrate surface 11 of target substrate 10 or target substrate 10 can comprise and be provided with structure 20 (e.g., steps 100 and 140 can be a common step).

Transfer element 40 can be a viscoelastic stamp 40 with a stamp post 42. In the present disclosure, for simplicity and clarity stamp 40 is referred to interchangeably with transfer element 40 but transfer element 40 is not limited to a stamp embodiment. Certain embodiments of the present disclosure contemplate and include transfer elements 40 other than stamps, for example vacuum, magnetic, and electro-static grippers that are used to print components 30, structures 20, or both components 30 and structures 20, to target substrate 10.

Some methods of the present disclosure accomplish component 30 transfers using micro-transfer printing (e.g., dry contact printing). Such printing methods can transfer components 30 formed on a native component source substrate. The component source substrate is processed to release components 30 from the component source substrate so that components 30 are physically attached to the component source substrate only with one or more component tethers 32 physically connecting components 30 to one or more anchors of the component source substrate. A stamp 40 contacts one or more components 30, adhering component 30 to stamp 40 (for example, to a stamp post 42). Stamp 40 separates and removes components 30 from the component source wafer, breaking (e.g., fracturing) or separating each component tether 32 physically connecting each component 30 to the native component source wafer. Stamp 40 then contacts the one or more components 30 adhered to stamp posts 42 to a target substrate 10 (e.g., to adhesive layer 12 coated on target-substrate surface 11.

Micro-transfer printing is especially useful when transferring or otherwise disposing components 30 that are relatively small. In some embodiments, for example, component 30 has a length, a width, or both a length and a width less than or equal to two hundred microns, e.g., less than or equal to one hundred microns, less than or equal to fifty microns, less than or equal to twenty microns, less than or equal to ten microns, less than or equal to five microns, less than or equal to two microns, or less than or equal to one micron in length or width and, optionally also has a thickness less than or equal to fifty microns, e.g., less than or equal to twenty five microns, less than or equal to ten microns, less than or equal to five microns, less than or equal to two microns, less than or equal to one micron, less than or equal to one-half micron, less than or equal to one-fifth micron, or less than or equal to one tenth micron.

According to some embodiments of the present disclosure, printed structure 99 can comprise aligned components 30 or structures 20 that receive, process, or emit light (e.g., are operable to receive, process, or emit light), such as photonic components 30 or photonic structures 20. Photonic components 30 or photonic structures 20 can be or include, for example, light pipes 24, light guides, or optical fibers that conduct light, light-emitting diodes, lasers, laser diodes, light sensors, or photodetectors. Thus, according to some embodiments of the present disclosure, structure 20, component 30, or both structure 20 and the component 30 are operable to receive, process, or emit light, both structure 20 and component 30 can comprise a light pipe and the light pipe in structure 20 can be in alignment with the light pipe in component 30, structure 20 can comprise a light pipe and component 30 can comprise a light emitter, light processor, or light sensor in alignment with the light pipe in structure 20, or component 30 comprises a light pipe and structure 20 comprises a light emitter, light processor, or light sensor in alignment with the light pipe in component 30.

In some embodiments, adhesive layer 12 is substantially transparent to light that is received or emitted by components 30 or structures 20. A substantially transparent adhesive layer 12 is one that does not compromise the effective transmission of light received or emitted by components 30 or structures 20, for example an adhesive layer 12 comprising an adhesive that is at least 50%, e.g., at least 75%, at least 80%, at least 85%, at least 90%, or at least 95% transparent to light received or emitted by components 30 or structures 20. In some embodiments, adhesive layer 12 can conduct light, for example serve as, or as a portion of, a light pipe (e.g., a light guide or fiberoptic channel) or can transmit light between component 30 and structure 20. In some embodiments, an encapsulation layer (for example, a dielectric layer) is disposed at least partly over any combination of component 30, structure 20, and any gap between component 30 and structure 20. An encapsulation layer can comprise a light-reflective layer or an encapsulation layer can be coated with a light-reflective layer. Such a light-reflective layer can control and direct light as desired with respect to components 30 and structures 20.

In some embodiments, emitted or received light is controlled or conducted by material optical-index differences, for example as in a fiber-optic device. According to some embodiments, component 30 or structure 20 comprises a component material, target substrate 10 comprises a substrate material, and the component material is substantially different from the substrate material, for example comprising different material, having different material transparency, reflection, or absorption, or having different optical indices (e.g., having at least a 10% difference in refractive index). In some embodiments, target substrate 10 comprises a reflective material disposed between component 30 and target substrate 10 or between structure 20 and target substrate 10.

According to some embodiments of the present disclosure, and as shown in FIGS. 6 and 7, structure 20 can have two or more structure sides 20E that are not co-planar (two or more structure faces 20E that are not in the same plane). Each individual structure face 20E can be planar or non-planar, for example comprising a non-planar shape such as a curve or other non-flat shape). Component 30 can have one or more component faces 30E complementary to the one or more structure faces 20E, for example component faces 30E matching those of structure 20, for example having inverse shapes. Complementary (e.g., matching) faces can fit closely together or can be in contact, or a portion of one face can fit into a matching or complementary other face. Such multiple component and structure faces 30E, 20E can assist alignment of component 30 with structure 20 to prevent component 30 from being undesirably rotated with respect to structure 20. Thus, in some embodiments, component 30 is disposed on target-substrate surface 11 of target substrate 10 within one micron (e.g., within 1.0 micron, within 0.75 micron, within 0.5 micron, within 0.25 micron, or within 0.1 micron) of the two-or-more non-planar faces of structure 20. In some embodiments, component 30 is disposed in contact with the two-or-more non-planar faces of structure 20 (and therefore has a spacing distance of zero microns). In some embodiments, a structure 20 and component 30 are within a spacing distance if any portion or structure face 20E of structure 20 is in contact with or within the spacing distance of any portion or component face 30E of component 30.

As shown in FIG. 1, in some embodiments, (i) structure 20 has a flat face opposed to component 30, (ii) component 30 has a substantially flat face 30E opposed to structure 20, or (iii) both (i) and (ii). The flat faces can be parallel to each other and thus enable close contact or a small spacing distance (e.g., less than one micron) between component and structure 20. In some embodiments, structure 20 has a non-planar face opposed to component 30 and component 30 has a non-planar face complementary to the face of structure 20. According to some embodiments, at least a portion of the non-planar face of structure 20 is in contact with the non-planar face of component 30.

In some embodiments of the present disclosure and as illustrated in FIGS. 8 and 9, printed structures 99 comprise multiple, spatially separated and independent alignment structures 20 that extend from target-substrate surface 11. Component 30 can be disposed in alignment with one or more of structures 20, for example in alignment with two structures 20, in alignment with three structures 20, in alignment with four structures 20, or in alignment with all of structures 20. Structures 20 facilitate alignment of component during micro-transfer printing component 30 to target-substrate surface 11 by providing mechanical (structural) stops to locate and orient component 30 in a desired spatial position and orientation as component 30 moves over target-substrate surface 11. Each component 30 can comprise a component substrate independent from and non-native to target substrate 10 or structures 20. Components 30 can be micro-transfer printed from a component source wafer to target-substrate surface 11 and consequently comprise a broken (e.g., fractured) or separated component tether 32.

As used herein, a length of component 30 is a dimension of component 30 that is longer than a width of component 30 in a horizontal direction H parallel to target-substrate surface 11. A component 30 can be longer in a length direction and shorter in a width direction and a component end is a side or face 30E of component 30 having a component edge 30E that is not parallel to the length direction. A component edge 30E can be orthogonal to the length direction (and parallel to the width direction) or not orthogonal to the length direction (and not parallel to the width direction. A horizontal direction H is parallel to target-substrate surface 11 and a vertical direction V is a direction orthogonal to target-substrate surface 11. Laterally means in a horizontal direction parallel to target-substrate surface 11.

In some embodiments, component 30 and one or more structures 20 are disposed in alignment with each other such that component 30 is laterally adjacent to one or more structures 20 and no other structure 20 is closer to component 30 than one or more structures 20, for example each of one or more structures 20 can be disposed in contact with or within a distance of five microns or less (e.g., two microns or less or one micron or less). Alignment between component 30 and structure 20 can also mean that component 30 has a component edge 30E (or component side 30E), structure 20 has a structure edge 20E (or structure side 20E), and component edge 30E and structure edge 20E are substantially parallel within manufacturing and design limitations.

Structures 20 and components 30 can have a substantially flat face substantially orthogonal to target-substrate surface 11, e.g., within manufacturing tolerances and limitations. Where structures 20 have a substantially flat structure face 20E (e.g., wall) that is not orthogonal to target-substrate surface 11, components 30 can have a component edge 30E (or component side 30E) that is no greater than one micron from a bottom of structure 20 adjacent to target-substrate surface 11 or no greater than one micron from a top of structure 20 on a side of structure 20 opposite target-substrate surface 11 (e.g., a top surface in a vertical direction opposite target-substrate surface 11). An edge of structure 20 or component 30 can also be a face, wall, or side of structure 20 or component 30.

Components 30 can be non-native to target substrate 10 (e.g., constructed on a separate native component source wafer and transferred to target substrate 10).

In some embodiments, structures 20 are constructed on and native to target substrate 10, for example formed by depositing materials such as inorganic dielectrics (e.g., silicon dioxide or silicon nitride) or organic dielectrics such as resins, epoxies, and photoresists (e.g., SU8, Intervia, or benzocyclobutene-based (BCB) polymers), and patterning the deposited materials to form structures 20. Structures 20 can comprise other elements, for example optical waveguides such as light pipes. In some embodiments, structures 20 can be disposed on and non-native to target-substrate surface 11 of target substrate 10 and any one or more of structures 20 can be a component 30 disposed in separate steps on target-substrate surface 11 so that a second component 30 can be aligned to a first component 30 acting as structure 20.

Multiple structures 20 can form mechanical stops for component 30 when micro-transfer printing component 30 onto target-substrate surface 11 of target substrate 10 or onto bottom target-substrate surface 11 of cavity 15 in target substrate 10 by physically moving component 30 horizontally toward or against structures 20. By using multiple structures 20 with spatial gaps or spatial separations between structures 20 (rather than a single structure 20 with a single structure edge 20E), broken (e.g., fractured) or separated component tethers 32 of component 30 can be disposed laterally between the separated structures 20 so that component tethers 32 do not form a mechanical standoff to structures 20 and do not prevent component 30 from aligning with (e.g., contacting) structures 20 when micro-transfer printing components 30 in alignment with structures 20. Structures 20 can extend from a wall or side of cavity 15 a greater distance than component tethers 32 extend from a side (e.g., edge or face) of component 30. Long and thin components 30, such as lasers, can require multiple component tethers 32 along the length of components 30 to enable micro-transfer printing. Embodiments of the present disclosure include methods and devices that prevent component tethers 32 from inhibiting alignment between components 30 and structures 20. For example, in some embodiments, component 30 is disposed on target-substrate surface 11 of target substrate within one micron (e.g., within 1.0 micron, within 0.75 micron, within 0.5 micron, within 0.25 micron, or within 0.1 micron) of at least one of structures 20, of two or more of structures 20, or all of structures 20 despite the presence of one or more component tethers 32 on component 30.

Furthermore, structure edges 20E of structures 20 can be arranged in a line so that a component edge 30E (e.g., a straight edge or side) of component 30 is substantially aligned with structures 20. Each structure 20 of two or more of structures 20 can have a structure edge 20E (or wall, e.g., a sidewall) and structure edges 20E (sidewalls) can be in a substantially straight line parallel to target-substrate surface 11 or in a plane substantially orthogonal to target-substrate surface 11. Components 30 are conveniently constructed with straight component edges 30E or component sides 30E to facilitate component 30 layout and construction. Component 30 can have one or more component edges 30E (e.g., component sides 30E) and at least one of component sides 30E can be substantially parallel to at least one of structure edges 20E. Thus, components 30 can be lined up with or along structures 20.

In some embodiments, some of structures 20 enable alignment between component 30 and a structure 20 with an optical element, for example alignment between a micro-transfer printed optical component 30 (e.g., a laser, photo sensor, optical amplifier, or optical modulator) with a light waveguide (e.g., a light pipe) in structure 20. Some of structures 20 can be arranged in a line (e.g., have structure edges 20E or structure sides 20E arranged in a line and another structure 20 can have an edge perpendicular to the line in alignment with component 30 so that the component sides 30E of component 30 are aligned with structures 20 in the line and a component end of component 30 (e.g., a component side 30E) is butted up against the other structure 20 so that a light-emitting or light-receiving part of component 30 can be optically aligned with light pipe. Component 30 can be moved horizontally in both x and y directions during micro-transfer printing (e.g., sequentially in either order or at the same time in a diagonal movement direction M as in FIG. 3D) to align component 30 with structures 20. Structures 20 can be arranged so that as component 30 is moved over target-substrate surface 11 structures 20 will tend to align component 30 as desired, for example by providing mechanical stops to prevent component 30 motion beyond a desired position. For example, if component 30 is rotated with respect to a desired position, structures 20 can prevent undesired rotation as component 30 moves into position. If component 30 is offset (e.g., horizontally offset in an x or y direction) with respect to a desired position, structures 20 can prevent undesired component 30 horizontal movement as component 30 moves into position in an x or y direction.

In some embodiments, structures 20 can have structure edges 20E that are disposed at an angle of substantially ninety degrees parallel to target-substrate surface 11 of target substrate 10 (e.g., orthogonal or perpendicular in a horizontal direction H). In some embodiments, structures 20 can have structure edges 20E that are disposed at an angle that is not orthogonal or perpendicular and is parallel to target-substrate surface 11 in a horizontal direction H. For example, structures 20 can have edges adjacent to component 30 that are arranged at an angle less than 90 degrees and structures 20 can have edges adjacent to component 30 that are arranged at an angle greater than 90 degrees. Non-orthogonal angles can further physically guide component 30 into alignment with structures 20 during micro-transfer printing where component 30 has opposing component ends in a length direction that are not parallel by converting a portion of component 30 movement direction M into a vector in the desired direction.

Component tethers 32 can be disposed along the length of component 30 and can be disposed laterally between structures 20. By separating structures 20 along component 30, structures 20 more readily guide component 30 into alignment for each structure 20 to position component 30 with respect to a desired position. To facilitate this, component 30 can be adjacent to more structures 20 along its length than along its width (e.g., is laterally adjacent to or in contact with more structures 20 along a longer side of component 30 than along a shorter side of component 30). If structures 20 were closer together, they would less effectively and accurately align edges of structures 20 with an edge of component 30 because the rotation of component 30 would be less controlled. Structures 20 can be made using photolithography and can, therefore, be extremely precise in size and location, for example having a size and location in contact with or within a few nanometers of a desired size and location. Thus, in embodiments of the present disclosure, structures 20 comprise a first structure 20 and a second structure 20. Component 30 can have a first component end and a second component end and first structure 20 can be disposed closer to the first component end than to the second component end and second structure 20 can be disposed closer to the second component end than to the first component end.

In some embodiments, structures 20 can be laterally adjacent to opposite component ends (e.g., component sides 30E) of component 30 and disposed at a non-orthogonal angle that so that as component 30 is moved horizontally, both component ends are guided into position and both opposite component ends are disposed in alignment or in contact with structures 20. The non-orthogonal angle can be open with edges that define lines parallel to target-substrate surface 11 that meet on a side of structures 20 opposite component 30 and in the direction of component 30 horizontal motion. This can be useful, for example, if light pipes are present in both structures 20 and optically aligned with both ends of component 30. For example, in a photonic device, component 30 can be an optical modulator or optical amplifier that inputs light from one structure 20 at one component end of component 30 and outputs modulated or amplified light at an opposite component end of component 30. Thus, in such embodiments, structures 20 comprise a first structure 20 having a first structure edge 20E and a second structure 20 having a second structure edge 20E, component 30 has a first component end having a first component edge 30E and an opposing second component end having a second component edge 30E. First structure edge 20E is at a non-orthogonal angle with respect to second structure edge 20E in a direction parallel to target-substrate surface 11, and first component edge 30E is substantially parallel to first structure edge 20E and second component edge 30E is substantially parallel to second structure edge 20E.

In some embodiments, components 30 are closely aligned with structures 20 formed on target substrate 10. Structures 20 can be substrate structures 20 and one or more sides or faces (e.g., component sides 30E) of components 30 can be in contact with or closely aligned to substrate structures 20, e.g., structure sides 20E within one micron, 500 nm, 200 nm, or 100 nm. Component 30 can comprise a broken (e.g., fractured) or separated component tether 32.

Aligning components 30 with structures 20 is very useful for photonic systems, for example comprising laser, light emitters such as diodes, waveguides (light pipes), optical amplifiers, and optical modulators. Optical components 30 are often constructed in or on relatively expensive compound semiconductor material wafers rather than relatively inexpensive glass, polymer, or silicon substrates. Moreover, silicon substrates can comprise light pipes (e.g., made with patterned silicon nitride on the silicon substrate) and substrate control circuits for controlling compound semiconductor components 30 in a photonic integrated circuit (e.g., a photonic system). Printed structures 99 of the present disclosure can be photonic structures, devices, or systems. Components 30 that are optically aligned with [e.g., due to close spatial proximity (e.g., within five microns, within two microns, within one micron)| light pipes in structures 20 have improved light coupling from component 30 to light pipe (or vice versa) and better optical system performance. Alignment between components 30 and one or more structures 20 can include both a close distance in any of three spatial dimensions (or a combination thereof) and a horizontal rotation to improve light coupling between optical components 30 and one or more light pipe(s) in one or more structures 20.

According to some embodiments of the present disclosure, an adhesive 12 (adhesive layer 12) such as an epoxy or resin is disposed on target-substrate surface 11 of target substrate 10, for example by spray or spin coating. Adhesive 12 can be disposed between component 30 and target-substrate surface 11 to adhere component 30 to target-substrate surface 11 and thereby facilitate micro-transfer printing component 30 onto target-substrate surface 11 and prevent component 30 from moving with respect to target-substrate surface 11 and structures 20 when subject to mechanical or thermal stress. In some embodiments, component 30 is contacted to adhesive 12 and then moved at least partially horizontally. It can be difficult to provide a layer of adhesive 12 that has a constant thickness and, because of capillary effects or because of spin coating non-uniformity due to topographic structures (e.g., structures 20), adhesive 12 can be thicker adjacent to structures 20, thereby making close and accurate alignment between component 30 and structure 20 difficult.

In the absence of embodiments of the present invention, adhesive 12 can be pushed by component 30 into a location directly between component 30 and structure 20 and form a bulge or protrusion of adhesive 12 in a vertical direction V and horizontal direction H preventing component 30 from moving into close alignment (e.g., in contact with) structure 20. By patterning adhesive 12 so that adhesive 12 is not in contact with and is separated from structure side 20E, such movement of adhesive 12 between components 30 and structures 20 is prevented or reduced. In some embodiments, the distance between adhesive 12 and structure side 20E is no less than fifty nm, one hundred nm, two hundred nm, five hundred nm, one micron, two microns, or five microns.

To facilitate micro-transfer printing, component 30 can have a thickness greater than a thickness of structures 20 (e.g., component 30 extends a greater vertical distance in vertical direction V from target-substrate surface 11 than structures 20) so that a micro-transfer printing device (e.g., a stamp 40 or stamp post 42) does not contact structures 20 during transfer or removal, as shown in FIGS. 3D and 3F.

Adhesive 12 is described in various embodiments as being, inter alia, separated from structure 20, on target substrate 10, beneath component 30, between component 30 and target substrate 10, and between structure 20 and target substrate 10. It should be understood that unless accompanied by the word “solely” or “exclusively” or a similar word, at least a portion of adhesive 12 can be disposed as described while a portion, or in some embodiments none, of adhesive 12 is disposed elsewhere. For example, when adhesive 12 is described as being disposed between component 30 and target substrate 10, it should be understood that some of adhesive 12 can be, but is not necessarily, disposed on target substrate 10 and not between component 30 and target substrate 10 (e.g., adhesive 12 extends along target substrate 10 beyond a perimeter of component 30 in at least one direction but not in contact with structure side 20E). For embodiments described that include adhesive 12 and where the word “solely” or “exclusively” or a similar word was not used in such description, additional analogous embodiments where adhesive 12 is disposed solely/exclusively as described (e.g., between component 30 and target substrate 10) are also contemplated. (Solely and exclusively are used interchangeably in this context with respect to adhesive 12.

Component 30 that is disposed in alignment with (e.g., is aligned to or aligned with) one or more structures 20 can be disposed within five microns, within two microns, within one micron, within 1.0 micron, or within 0.5 micron of or in contact with each of one or more structures 20. In some embodiments, a component face 30E of component 30 can be within ±10 degrees (e.g., within ±8 degrees, within ±6 degrees, within ±4 degrees, or within ±2 degrees) of parallel to a structure face 20E of structure 20 when component 30 is aligned with structure 20. In some embodiments, component 30 is aligned with one or more structures 20 in that component 30 is disposed in optical alignment with one or more structures 20, for example when component 30 is an optical component and structure 20 includes one or more optical elements, such as a waveguide, optical amplifier, optical modulator, or combination thereof (such that structure 20 is itself an optical component). When component 30 and one or more structures 20 are optically aligned, light from component 30 can be received by (e.g., processed by) one or more optical elements in structure(s) 20. Printing component 30 to target substrate 10 by contacting component 30 to one or more structures 20 during printing aligns component with one or more structures 20. Component 30 will not necessarily, but can, physically contact each of one or more structures 20 after printing, for example each of one or more structures 20 can be separated from component 30 by a small distance of no more than one micron. In some embodiments, printed structure 99 is designed to have component be disposed in a certain location relative to one or more structures 20 such that component 30 is then considered aligned with one or more structures 20 when disposed within a certain tolerance (e.g., no more than five microns, no more than two microns, no more than one micron, or no more than one-half micron) of the certain location; such one or more structures 20 can facilitate such disposition, for example during printing. In some embodiments, component 30 is disposed at the certain location to within manufacturing (e.g., printing) tolerances.

Reference is made throughout the present description to examples of printing that are micro-transfer printing with stamp 40 comprising stamp post 42 when describing certain examples of printing components 30. Similar other embodiments are expressly contemplated where a transfer element 40 that is not a stamp 40 is used to similarly print components 30. For example, in some embodiments, a transfer element 40 that is a vacuum-based, magnetic, or electrostatic transfer element 40 can be used to print components 30. A component 30 can be adhered to a transfer element 40 with any type of force sufficient to maintain contact between the component 30 and transfer element 40 when desired and separate transfer element 40 from component 30 when desired. For example, component 30 can be adhered to transfer element 40 with one or more of an adhesion, electrostatic, van der Waals, magnetic, or vacuum force. In some embodiments, adhesion between component 30 and transfer element 40 occurs at least in part due to a force generated by operating transfer element 40 (e.g., an electrostatic force) and separation of transfer element 40 from component 30 occurs at least in part by ceasing provision of the force (e.g., an electrostatic force). Similar transfer elements 40 can be used to print structures 20. A vacuum-based, magnetic, or electrostatic transfer element can comprise a plurality of transfer posts, each transfer post being constructed and arranged to pick up a single component 30 (similarly to stamp posts 42 in stamp 40).

According to some embodiments, micro-transfer printing can include any method of transferring components 30 from a component source wafer (e.g., a native source wafer) to a target substrate 10 by contacting components 30 on the component source wafer with a patterned or unpatterned stamp surface of a stamp 40 (e.g., a distal end of stamp post 42), removing (e.g., separating) components 30 from the component source wafer, transferring stamp 40 and contacted components 30 to target substrate 10, and contacting components 30 to target-substrate surface 11 of target substrate 10, for example adhesive layer 12 by moving stamp 40 or target substrate 10. Components 30 can be adhered to stamp 40 or target substrate 10 by, for example, van der Waals forces, electrostatic forces, magnetic forces, chemical forces, adhesives, or any combination of the above. In some embodiments, components 30 are adhered to stamp 40 with separation-rate-dependent adhesion, for example kinetic control of viscoelastic stamp materials such as can be found in elastomeric transfer elements 40 or transfer devices such as a PDMS stamp 40. Stamps 40 can be patterned or unpatterned and can comprise stamp posts 42 having a stamp post area on the distal end of stamp posts 42. Stamp posts 42 can have a length, a width, or both a length and a width, similar or substantially equal to a length, a width, or both a length and a width of component 30.

In exemplary methods, a viscoelastic elastomer (e.g., PDMS) stamp 40 (e.g., comprising a plurality of stamp posts 42) is constructed and arranged to retrieve and transfer arrays of components 30 from their native component source wafer onto non-native patterned target substrates 10. In some embodiments, stamp 40 mounts onto motion-plus-optics machinery (e.g., an opto-mechatronic motion platform) that can precisely control stamp 40 alignment and kinetics with respect to both component source wafers and target substrates 10. During micro-transfer printing, the motion platform brings stamp 40 into contact with components 30 on the component source wafer, with optical alignment performed before contact. Rapid upward movement of the print-head (or, in some embodiments, downward movement of the component source wafer) breaks (e.g., fractures) or separates component tether(s) 32 forming broken (e.g., fractured) or separated component tethers 32, transferring component(s) 30 from native component source wafer to stamp 40 or stamp posts 42. Stamp 40 populated with components 30 then travels to patterned target substrate 10 (or vice versa) and one or more components are then aligned to target substrate 10 and printed.

A component source wafer can be any source wafer or substrate with (e.g., native) transfer-printable components 30 that can be transferred with a transfer element 40 (e.g., a stamp 40). For example, a component source wafer can be or comprise a semiconductor (e.g., silicon) in a crystalline or non-crystalline form, a compound semiconductor (e.g., comprising GaN or GaAs), a glass, a polymer, a sapphire, or a quartz wafer. Sacrificial portions of native component source wafer enabling the release of components 30, for example by etching, can be formed of a patterned oxide (e.g., silicon dioxide) or nitride (e.g., silicon nitride) layer or can be an anisotropically etchable portion of a sacrificial layer of a component source wafer over which components 30 are disposed while also physically connected by component tether 32 to an anchor of the component source wafer. Typically, component source wafers are smaller than patterned target substrates 10 and can have a higher density of components 30 disposed thereon than components 30 disposed on target substrate 10.

Components 30 can be any transfer-printable element, for example including any one or more of a wide variety of active or passive (or active and passive) components 30 (e.g., devices or subcomponents). Components 30 can be any one or more of integrated devices, integrated circuits (such as CMOS circuits), light-emitting diodes, photodiodes, sensors, electrical or electronic devices, optical devices, opto-electronic devices, magnetic devices, magneto-optic devices, magneto-electronic devices, and piezo-electric device, materials or structures. Components 30 can comprise electronic component circuits electrically connected to electrodes that operate component 30. Component 30 can be responsive to electrical energy, to optical energy, to electromagnetic energy, or to mechanical energy, or a combination thereof, for example. In some embodiments, an electro-optic device comprises component 30 (e.g., and, optionally, structure 20). In some embodiments, components 30 are light emitters, for example are one or more of light-emitting diodes, lasers, diode lasers, vertical-cavity surface-emitting lasers, micro-lasers, micro-light-emitting diodes, organic light-emitting diodes, inorganic light-emitting diodes, quantum-dot based light emitters, and super-luminescent diodes.

Components 30 formed or disposed in or on component source wafers can be constructed using integrated circuit, micro-electro-mechanical, or photolithographic methods for example. Components 30 can comprise one or more different component materials, for example non-crystalline (e.g., amorphous), polycrystalline, or crystalline semiconductor materials such as silicon or compound semiconductor materials or non-crystalline or crystalline piezo-electric materials. In some embodiments, component 30 comprises a layer of dielectric material, for example an oxide or nitride such as silicon dioxide or silicon nitride.

In certain embodiments, components 30 can be native to and formed on sacrificial portions of component source wafers and can include seed layers for constructing crystalline layers on or in component source wafers. Components 30, sacrificial portions, anchors, and component tethers 32 can be constructed, for example using photolithographic processes. Components 30 can be micro-devices having at least one of a length and a width less than or equal to two hundred microns, e.g., less than or equal to one hundred microns, less than or equal to fifty microns, less than or equal to twenty five microns, less than or equal to fifteen microns, less than or equal to ten microns, or less than or equal to five microns, and alternatively or additionally a thickness of less than or equal to fifty microns, e.g., less than or equal to twenty five microns, less than or equal to fifteen microns, less than or equal to ten microns, less than or equal to five microns, less than or equal to two microns, or less than or equal to one micron. Components 30 can be unpackaged dice (each an unpackaged die) that, in some embodiments, are transferred directly from one or more (e.g., native) component source wafers on or in which components 30 are constructed to target substrate 10. Anchors and component tethers 32 can each be or can comprise portions of a native component source wafer that are not sacrificial portions and can include layers formed on component source wafers, for example dielectric or metal layers and for example layers formed as a part of photolithographic processes used to construct or encapsulate components 30.

Target substrate 10 can be any destination substrate or target substrate 10 to which components 30 are transferred (e.g., micro-transfer printed), for example flat-panel display substrates, printed circuit boards, semiconductor wafers, or similar substrates can be used in various embodiments. Target substrates 10 can be, for example substrates comprising one or more of glass, polymer, quartz, ceramics, metal, silicon, and sapphire. Target substrates 10 can be semiconductor substrates (for example silicon) or compound semiconductor substrates. In some embodiments, target substrate 10 is a semiconductor substrate and comprises an electronic substrate circuit. Electronic substrate circuits can be electrically connected through electrodes to control, provide signals to, or respond to component 30.

In some embodiments, an adhesive layer 12 of adhesive, such as a layer of resin, polymer, or epoxy, either curable or non-curable, adheres components 30 onto target substrate 10 and can be disposed, for example by coating or lamination. In some embodiments, an adhesive layer 12 is disposed in a pattern, for example disposed in locations on target substrate 10 where components 30 are to be printed (e.g., micro-transfer printed). A patterned layer of adhesive 12 can be disposed using inkjet, screening, or photolithographic techniques, for example. In some embodiments, adhesive layer 12 is coated, for example with a spray or slot coater, and then patterned, for example using photolithographic techniques. If an adhesive 12 is disposed over at least a portion of target-substrate surface 11 of target substrate 10, a component 30 disposed on adhesive 12 is also said to be disposed on target-substrate surface 11. In some embodiments, structures 20 are disposed on an adhesive 12. In some embodiments, components 30 are disposed on an adhesive 12. In some embodiments, both components and structures 20 are disposed on an adhesive 12 (e.g., a common adhesive layer 12).

Patterned electrical conductors (e.g., wires, traces, or electrodes such as electrical substrate contact pads found on printed circuit boards, flat-panel display substrates, and in thin-film circuits) can be formed on any combination of components 30, structures 20, and target substrate 10, and any one can comprise electrical conductors such as wires or electrical contact pads that electrically connect to components 30 or structures 20. Such patterned electrical conductors and electrodes (e.g., contact pads) can comprise, for example, metal, transparent conductive oxides, or cured conductive inks and can be constructed using photolithographic methods and materials, for example metals such as aluminum, gold, or silver deposited by evaporation and patterned using pattern-wise exposed, cured, and etched photoresists, or constructed using imprinting methods and materials or inkjet printers and materials, for example comprising cured conductive inks deposited on a surface 11 or provided in micro-channels in or on target substrate 10.

Examples of micro-transfer printing processes suitable for disposing components onto target substrates 10 are described in Inorganic light-emitting diode displays using micro-transfer printing (Journal of the Society for Information Display, 2017, DOI #10.1002/jsid.610, 1071-0922/17/2510-0610, pages 589-609), U.S. Pat. No. 8,722,458 entitled Optical Systems Fabricated by Printing-Based Assembly, U.S. Pat. No. 10,103,069 entitled Pressure-Activated Electrical Interconnection by Micro-Transfer Printing, U.S. Pat. No. 8,889,485 entitled Methods for Surface Attachment of Flipped Active Components, U.S. patent application Ser. No. 14/822,864 entitled Chiplets with Connection Posts, U.S. Pat. No. 10,224,460 entitled Micro-Assembled LED Displays and Lighting Elements, and U.S. Pat. No. 10,153,256, entitled Micro-Transfer Printable LED Component, the disclosure of each of which is incorporated herein by reference in its entirety.

For a discussion of various micro-transfer printing techniques, see also U.S. Pat. Nos. 7,622,367 and 8,506,867, each of which is hereby incorporated by reference in its entirety. Micro-transfer printing using compound micro-assembly structures and methods can also be used in certain embodiments, for example, as described in U.S. patent application Ser. No. 14/822,868, filed Aug. 10, 2015, entitled Compound Micro-Assembly Strategies and Devices, which is hereby also incorporated by reference in its entirety. In some embodiments, any one or more of component 30, structure 20, and printed structure 99 is a compound micro-assembled structure (e.g., a compound micro-assembled macro-system).

According to various embodiments, a component source wafer (e.g., a native component source wafer) can be provided with components 30, patterned sacrificial portions, component tethers 32, and anchors already formed, or they can be constructed as part of a method in accordance with certain embodiments. Component source wafers and components 30, transfer element 40 (e.g., a stamp 40), and target substrate 10 can be made separately and at different times or in different temporal orders or locations and provided in various process states.

The spatial distribution of any one or more of components 30 and structures 20 is a matter of design choice for the end product desired. In some embodiments, all components 30 in an array on a component source wafer are transferred to a transfer element 40. In some embodiments, a subset of components 30 in an array on a native component source wafer is transferred. By varying the number and arrangement of stamp posts 42 on transfer stamps 40, the distribution of components 30 on stamp posts 42 of transfer stamp 40 can be likewise varied, as can the distribution of components 30 and structures 20 on target substrate 10.

Structures 20 can be disposed or constructed in an array on target substrate 10. For example, structures 20 can be disposed by printing (e.g., micro-transfer printing) them onto target substrate 10 or forming them using photolithographic methods and materials. Structures 20 can be disposed in a regular array. Structures 20 can be disposed in an array having a linear density in one or two dimensions. The linear density can be, for example, no more than 200 structures 20 per mm and/or no less than 0.1 structure 20 per mm. Components 30 can be disposed in an array (e.g., a regular array) that corresponds to the array (e.g., regular array) in which structures 20 are disposed.

Because components 30, in certain embodiments, can be made using integrated circuit photolithographic techniques having a relatively high resolution and cost and target substrate 10, for example a printed circuit board, can be made using printed circuit board techniques having a relatively low resolution and cost, electrical conductors (e.g., electrodes) can be much larger than electrical contacts or component electrodes on component 30, thereby reducing manufacturing costs. For example, in certain embodiments, printable component 30 has at least one of a width, length, and height from one-half microns to two hundred microns (e.g., one-half to two microns, two to five microns, five to ten microns, ten to twenty microns, twenty to fifty microns, fifty to one hundred microns, or one hundred to two hundred microns).

In certain embodiments, target substrate 10 is or comprises a member selected from the group consisting of polymer (e.g., plastic, polyimide, PEN, or PET), resin, metal (e.g., metal foil) glass, a semiconductor, and sapphire. In certain embodiments, a target substrate 10 has a thickness from five microns to twenty mm (e.g., five to ten microns, ten to twenty microns, twenty to fifty microns, fifty to one hundred microns, one hundred to two hundred microns, two hundred to five hundred microns, five hundred to one thousand microns, one mm to five mm, five mm to ten mm, or ten mm to twenty mm).

Components 30, in certain embodiments, can be constructed using foundry fabrication processes used in the art. Layers of materials can be used, including materials such as metals, oxides, nitrides and other materials used in the integrated-circuit art. Each component 30 can be or include a complete semiconductor integrated circuit and can include, for example, any combination of one or more of a transistor, a diode, a light-emitting diode, and a sensor. Components 30 can have different sizes, for example, at least one hundred square microns (e.g., at least one thousand square microns, at least ten thousand square microns, at least one hundred thousand square microns, or at least one square mm). Alternatively, or additionally, components 30 can be no more than one hundred square microns (e.g., no more than one thousand square microns, no more than ten thousand square microns, no more than one hundred thousand square microns, or no more than one square mm). Components 30 can have variable aspect ratios, for example from 1:1 to 10:1 (e.g., 1:1, 2:1, 5:1, or 10:1). Components 30 can be rectangular or can have other shapes, such as polygonal or circular shapes for example.

Various embodiments of structures and methods were described herein. Structures and methods were variously described as transferring components 30, printing components 30, or micro-transferring components 30. In some embodiments, micro-transfer-printing involves using a transfer element 40 (e.g., an elastomeric stamp 40, such as a PDMS stamp 40) to transfer a component 30 using controlled adhesion. For example, an exemplary transfer device can use kinetic or shear-assisted control of adhesion between a transfer element 40 and a component 30. It is contemplated that, in certain embodiments, where a method is described as including printing (e.g., micro-transfer-printing) a component 30, other similar embodiments exist using a different transfer method. In some embodiments, transferring or printing a component 30 (e.g., from a native component source substrate or wafer to a destination patterned target substrate 10) can be accomplished using any one or more of a variety of known techniques. For example, in certain embodiments, a pick-and-place method can be used to print components 30 or structures 20. As another example, in certain embodiments, a flip-chip method can be used (e.g., involving an intermediate, handle or carrier substrate). In methods according to certain embodiments, a vacuum tool, an electro-static tool, a magnetic tool, or other transfer device is used to transfer a component 30.

The figures that show transfer element 40 are simplified to show transfer element printing a single component 30. In some embodiments, a single component 30 is printed using transfer element 40 in a single print step. In some embodiments, a plurality of components is printed using transfer element 40 in a single print step. For example, in some embodiments, at least ten components 30, e.g., at least fifty components 30, at least one hundred components 30, at least lone thousand components 30, at least ten thousand components 30, or at least fifty thousand components 30 can be or are printed in a single print step.

Those of ordinary skill in the art will appreciate that high-precision structures, components therefor, and methods of making that can be adapted into, applied to, and/or used with embodiments disclosed in the present application are disclosed in U.S. Pat. No. 10,714,374, the disclosure of which is hereby incorporated by reference in its entirety.

As is understood by those skilled in the art, the terms “over” and “under” are relative terms and can be interchanged in reference to different orientations of the layers, elements, and substrates included in various embodiments of the present disclosure. Furthermore, a first layer or first element “on” a second layer or second element, respectively, is a relative orientation of the first layer or first element to the second layer or second element, respectively, that does not preclude additional layers being disposed therebetween. For example, a first layer on a second layer, in some implementations, means a first layer directly on and in contact with a second layer. In other implementations, a first layer on a second layer includes a first layer and a second layer with another layer therebetween (e.g., and in mutual contact).

Having described certain implementations of embodiments, it will now become apparent to one of skill in the art that other implementations incorporating the concepts of the disclosure may be used. Therefore, the disclosure should not be limited to certain implementations, but rather should be limited only by the spirit and scope of the following claims.

Throughout the description, where apparatus and systems are described as having, including, or comprising specific elements, or where processes and methods are described as having, including, or comprising specific steps, it is contemplated that, additionally, there are apparatus and systems of the disclosed technology that consist essentially of, or consist of, the recited elements, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The disclosure has been described in detail with particular reference to certain embodiments thereof, but it will be understood that variations and modifications can be effected within the spirit and scope of the following claims.

### PARTS LIST

H horizontal direction
M movement direction
S separation distance
V vertical direction
10 target substrate
11 surface/substrate surface/cavity bottom surface
12 adhesive/adhesive layer/patterned adhesive layer
15 cavity
20 structure/alignment structure/substrate structure
20E structure side/structure edge/structure face
30 component
30E component side/component edge/component face
32 component tether/broken (e.g., fractured) or separated component tether
40 stamp/transfer element
42 stamp post
99 printed structure
100 provide substrate step
110 provide component source substrate step
120 provide stamp step
130 pick up components with stamp step
140 form structures on substrate step
150 dispose adhesive step
155 pattern adhesive step
160 print components onto substrate with stamp step
170 separate stamp step
180 cure adhesive step

1. A printed structure, comprising:
a target substrate having a target-substrate surface;
a structure disposed in or on the target substrate, the structure having a structure side;
a patterned adhesive layer disposed on the target-substrate surface not in contact with the structure side; and
a component having a component side, the component disposed on the patterned adhesive layer with the component side adjacent to the structure side.

2. The printed structure of claim 1, wherein the component side is within one micron of the structure side.

3. The printed structure of claim 1, wherein the component is non-native to the target substrate and non-native to the structure.

4. The printed structure of claim 1, wherein the component comprises a broken or separated component tether.

5. The printed structure of claim 4, wherein the component tether is disposed on a second side of the component different from the component side.

6. The printed structure of claim 1, wherein the structure side is substantially planar.

7. The printed structure of claim 1, wherein the structure comprises two adjacent structure sides, the component comprises two adjacent component sides, the patterned adhesive layer is disposed on the target-substrate surface not in contact with either of the two adjacent structure sides, and the component is disposed on the adhesive layer with each of the two adjacent component sides adjacent to a corresponding one of the two adjacent structure sides.

8. The printed structure of claim 1, wherein the adhesive layer has a thickness over the target substrate that is no greater than one micron.

9. The printed structure of claim 1, comprising a cavity extending into the target substrate, wherein the cavity comprises a cavity bottom and cavity walls, the cavity bottom is at least a portion of the target-substrate surface, and the structure comprises a portion of the target substrate forming the cavity, and the cavity wall forms the structure side.

10. The printed structure of claim 1, wherein the adhesive layer comprises a soft-cured adhesive.

11. The printed structure of claim 1, wherein the adhesive layer comprises a hard-cured adhesive.

12. The printed structure of claim 1, wherein the component side is in physical contact with the structure side.

13. The printed structure of claim 1, wherein the component side is substantially parallel to the structure side.

14. The printed structure of claim 1, comprising multiple components each non-native to the target substrate and each having a component side disposed adjacent to the structure side.

15. The printed structure of claim 1, comprising two or more structures.

16. The printed structure of claim 15, wherein the component side is substantially parallel to the structure sides.

17. The printed structure of claim 15, wherein the structure sides are not parallel.

18. The printed structure of claim 15, wherein the structure sides form an angle less than 180 degrees.

19. The printed structure of claim 18, wherein the component is disposed within the angle formed by the structure sides.

20. The printed structure of claim 1, wherein (i) the component side is substantially orthogonal to the target-substrate surface, (ii) the structure side is substantially orthogonal to the target-substrate surface, or (iii) both (i) and (ii).

21. A method of making a printed structure, comprising:
providing a target substrate and one or more structures extending from a target-substrate surface of the target substrate and wherein each of the one or more structures has a structure side;
providing a patterned adhesive layer on the target-substrate surface of the target substrate so that the adhesive layer is not in contact with the structure side;
providing a transfer element and a component adhered to the transfer element;
disposing the component on the adhesive layer with the transfer element; and
separating the transfer element from the component, thereby printing the component to the target substrate.

22. The method of claim 21, comprising moving the transfer element with the adhered component horizontally towards at least one of the structures at least until the component side physically contacts a structure side of at least one of the structures before the component is disposed on the adhesive layer with the transfer element.

23. The method of claim 21, comprising moving the transfer element with the adhered component horizontally towards at least one of the structures at least until the component side physically contacts a structure side at least one of the structures after the component is disposed on the adhesive layer with the transfer element.

24. The method of claim 21, comprising moving the transfer element with the adhered component horizontally towards at least one of the structures at least until the component side physically contacts a structure side at least one of the structures at the same time that the component is moved vertically and disposed on the adhesive layer with the transfer element.

25. The method of claim 21, wherein the one or more structures comprise two or more structures having sides forming an angle less than 180 degrees and wherein the transfer element moves the component horizontally towards two structure sides (i) at the same time or (ii) sequentially.
